(19) United States
(12) Patent Application Publication
(10) Pub. No.: US 2012/0122029 A1
(43) Pub. Date: May 17, 2012

(54) Underlayer Developable Coating Compositions and Processes Thereof

(76) Inventors: Takanori Kudo, Bedminster, NJ (US); Alberto Dioses, Doylestown, PA (US); Edward Ng, Belle Mead, NJ (US); Srinivasan Chakrapani, Bridgewater, NJ (US); Munirathna Padmanaban, Bridgewater, NJ (US)

(21) Appl. No.: 12/944,420

(22) Filed: Nov. 11, 2010

(51) Int. Cl. G03F 7/004; G03F 7/20

(52) U.S. Cl. 430/270.1; 430/325

(57) ABSTRACT

The present invention relates to a photoimageable underlayer composition comprising a polymer, a crosslinker comprising a vinyl ether group, and a thermal acid generator comprising a salt of a mono or polycarboxylic acid and an amine, where the amine has a boiling point of at least 150° C. The invention also relates to a process for forming an image in the underlayer comprising the novel composition.

### FIELD OF THE INVENTION

The present invention relates to novel aqueous developable underlayer coating, compositions useful as coating layers in multilayer systems, especially coated below photoresist, and processes for using the novel coatings.

### DESCRIPTION

Photoresist compositions are used in microlithography processes for making miniaturized electronic components such as in the fabrication of computer chips and integrated circuits. Generally, in these processes, a thin coating of a film of a photoresist composition is first applied to a substrate material, such as silicon wafers used for making integrated circuits. The coated substrate is then baked to evaporate any solvent in the photoresist composition and to fix the coating onto the substrate. The baked and coated surface of the substrate is next subjected to an image-wise exposure to radiation. The radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the photoresist.

There are two types of photoresist compositions, negative-working and positive-working. When positive working photoresist compositions are exposed image-wise to radiation, the areas of the photoresist composition exposed to the radiation become soluble in a developer solution while the unexposed areas of the photoresist coating remain relatively insoluble to such a solution. Thus, treatment of an exposed positive-working photoresist with a developer causes removal of the exposed areas of the photoresist coating and the formation of a positive image in the coating, thereby uncovering a desired portion of the underlying substrate surface on which the photoresist composition was deposited. In a negative-working photoresist the developer removes the portions that are not exposed.

The trend towards the miniaturization of semiconductor devices has led both to the use of new photoresists that are sensitive to lower and lower wavelengths of radiation, and also to the use of sophisticated multilevel systems to overcome difficulties associated with such miniaturization.

In these multilevel or multilayer systems, for example, the use of underlayer coatings in photolithography is a simpler approach to diminish the problems that result from lithographic difficulties. A developable bottom underlayer coating is applied on the substrate and then a layer of photoresist is applied on top of the antireflective coating. The photoresist is exposed imagewise and developed with an aqueous alkaline developer. The developable bottom underlayer coating is also developable with the same aqueous alkaline developing solution as that used to typically develop the photoresist, that is, the exposed regions of the photoresist and the underlayer are removed by the developer. Additionally, barrier coatings or top antireflective coatings or immersion protection coatings are also used in multilayer systems. Generally, developable bottom underlayer coating composition comprises a polymer which is initially insoluble, in the solvent of the photoresist composition, but becomes soluble in an aqueous alkaline developer prior to development. In some cases the underlayer coating comprises a thermal acid generator comprising a reaction product of an acid and a volatile amine. The volatile amine has been desirable so that it can be removed during curing so as not to interfere with the subsequent acid catalysed decrosslinking of the underlayer coating. However, the applicants have found that amines which are not volatile and are used to form the thermal acid generator, can provide benefit in certain lithographic applications.

The present invention relates to a novel aqueous alkaline developable underlayer coating composition comprising a polymer, a crosslinker and a thermal acid generator, where the thermal acid generator is a salt of an acid and an amine, and where the amine has a boiling point of at least 150° C. Amines with boiling point higher than 150° C. have been unexpectedly found to provide better lithographic properties than volatile amines with boiling point less than 150° C. The invention also relates to a process for imaging using the novel composition.

### BRIEF DESCRIPTION OF THE DRAWING

FIG. 1 shows the various types of polymers.

FIG. 2 shows further types of polymers.

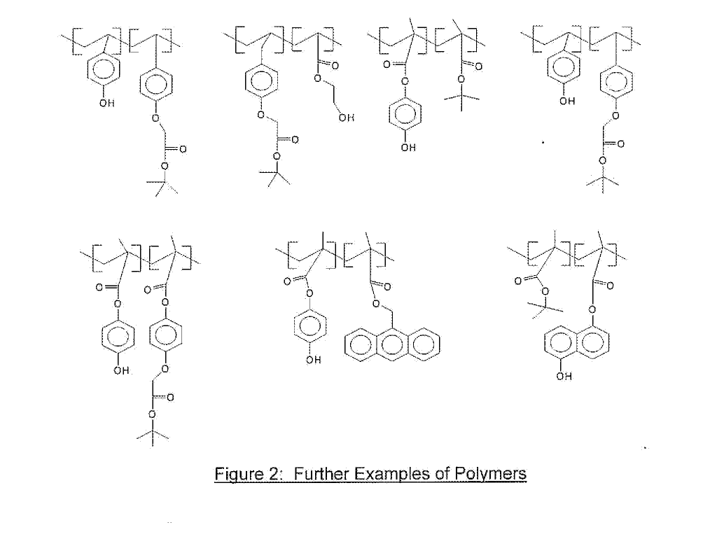

FIG. 3 shows more types of polymers.

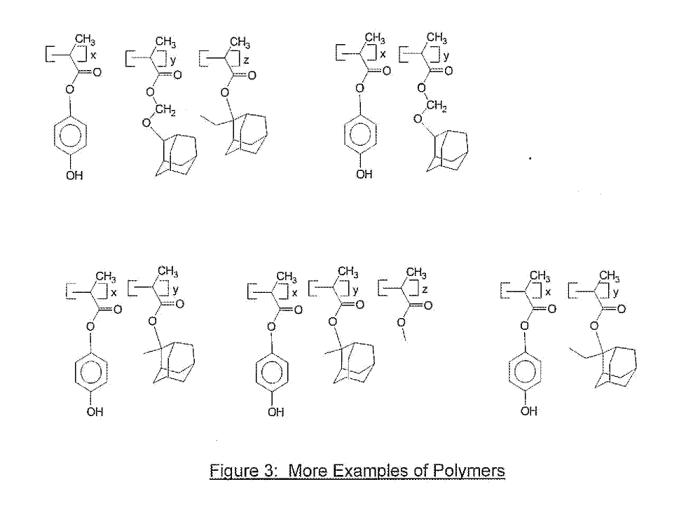

### SUMMARY OF THE INVENTION

The present invention relates to a photoimageable underlayer composition comprising a polymer, a crosslinker comprising a vinyl ether group, and a thermal acid generator comprising a salt of a mono or polycarboxylic acid and an amine, where the amine has a boiling point of at least 150° C. The invention also relates to a process for forming an image in the underlayer comprising the novel composition.

### DETAILED DESCRIPTION OF THE INVENTION

The present invention relates to a novel aqueous developable underlayer coating composition comprising a polymer, a crosslinker comprising vinyl ether group and a thermal acid generator, where the thermal acid generator comprises an amine salt of a mono or polycarboxylic acid, and where the amine has a boiling point of at least 150° C. The thermal acid generator may be of structure (1) or (2) described below. The present invention also relates to a process for forming an image on a substrate using the novel composition.

The novel underlayer, which is a positive bottom photoimageable antireflective coating composition and is developed with an aqueous alkali developer to form an image, and which is coated below a positive photoresist, comprises a polymer, a crosslinker comprising a vinyl ether group and a thermal acid generator (salt), where the salt is formed from an amine compound and a mono or polycarboxylic acid. The crosslinker has at least 2 vinyl ether groups for crosslinking with the polymer. The resulting acetal linkages formed by the crosslinking of the polymer and the crosslinker, are easily cleavable in the presence of photogenerated acids.

The thermal acid generator is a salt of an acid and an amine. The acids used to form the thermal acid generator have moderate acidity, i.e. With a pKa (− log₁₀ of the acid dissociation constant) greater than 1.0 are preferred, especially when using a vinyl ether terminated crosslinking agent. Acids with a pKa of less than 6.5 and greater than 1.0 are also preferred. Examples, without limitations, of acids forming the thermal acid generators with moderate acidity are maleic acid. (pKa of 1.83 & 6.07), chloroacetic acid (pKa of 2.85), dichloroacetic acid (pKa of 1.48), oxalic acid (pKa of 1.23 & 4.19), trans-cinnamic acid (pKa of 4.44), α-tartaric acid (pKa of 2.98 & 4.34), gylcolic acid (pKa of 3.83), trans-fumaric acid (pKa of 3.03 & 4.44), malonic acid (pKa of 2.83 & 5.69), cyanoacetic acid (pKa of 2.45), etc. Acids, such as those described above, are blocked with bases such as amines. The amines have a boiling point of at least 150° C. Specific non restrictive example of carboxylic acids that forms the salt are oxalic acid, 1-chloroacetic acid, glycolic acid, glutaric acid, cyanoacetic acid, maleic acid, malonic acid, fumaric acid, malic acid, tartaric acid, citric acid, heptanoic acid, hexanoic acid, butanoic acid, 2-hydroxyisobutyric acid, cyclohexanecarboxylic acid, 1,3,5-cyclohexanetricarboxylic acid, benzoic acid, citric acid, butyric acid and the like.

The thermal acid generator or salt may have the structure (1) or (2). Furthermore, the amine compound used to form the salt has a boiling point greater than or equal to 150° C. Structure 1 and 2, are represented as below,

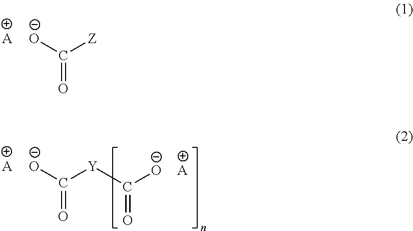

where, A is an amino cation, Z is an organic group, such as (C₁-C₂₀)alkyl, substituted (C₁-C₂₀)alkyl, (C₂-C₂₀)alkenyl, substituted (C₂-C₂₀)alkynyl, substituted (C₁-C₂₀) alkyl containing at least one heteroatom, substituted (C₂-C₂₀) alkenyl containing at least one heteroatom, substituted alkynyl (C₂-C₂₀) containing at least one heteroatom, (C₆-C₂₀)aryl, and substituted (C₆-C₂₀)aryl; and the connecting group Y can be selected from a direct valence bond or a divalent organic group, and, n=1-5. The divalent organic group may be C₁-C₈ alkylene, substituted C₁-C₈ alkylene, C₁-C₈ alkylene containing one or more hetero atom groups, substituted C₁-C₈ alkylene containing one or more hetero atom groups, C₃-C₈ cycloalkylene, substituted C₃-C₈ cycloalkylene, C₂-C₈ unsubstituted or substituted alkenylene (—C═C—), unsustituted or substituted alkynylene (—C₂—), and C₆-C₁₂, unsubstituted or substituted arylene, which may also contain optional hetero atom. Substituents for the above described groups can consist of alkyl, aryl, cyano, hydroxyl, nitro, carbonylalkyl, hydroxyalkyl and the like. Examples of hetero atoms are O, S, SO, SO₂, —C(═O)—O—, O—C(═O)—O, —OC(═O)—), etc. In structure 2, the spacer group, Y, may also consist of a mixture of the different types of spacer groups as previously described above. The amine of the amino cation A has a boiling point of at least 150° C. The amino cation A is not an ammonium ion (NH₄), and comprises at least one organic group attached to the nitrogen of the amine.

The amino compound of the thermal acid generator, AH, which is the protonated form of the amino cation A⁺ in structure 1 and 2, can be selected so that it has a boiling point high enough such that it a substantial amount remains in the polymer film after a higher curing bake cycle of the underlayer coating, for example curing from about 180° C. to about, 205° C. for about 30 to about 90 seconds. It is believed that the amino cation is present in the film after the curing bake, especially at higher temperatures exceeding 180° C. A substantial amount of the amino compound remains in the baked film by selecting amino compounds for neutralizing the carboxylic acid or polycarboxylic acid compound which have a boiling point of at least 150° C., or have a boiling point of at least 180° C., or have a boiling point above 210° C., or have a boiling point of at least 240° C. Examples of the amine compound used to form the salt include a compound selected from the group consisting of structures 3, 4, 5 and 6, in which the amino group is present as a non-cyclic amine, a cyclic amine, multicyclic amine or an aromatic amine;

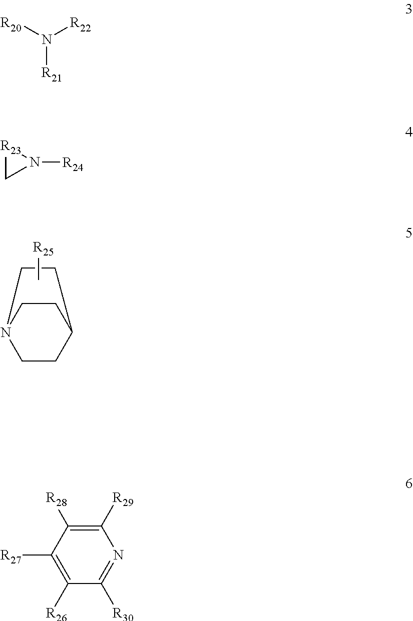

In structure 3, R₂₀, R₂₁, R₂₂, are individually selected from hydrogen, C₁-C₂₀ alkyl, substituted C₁-C₂₀ alkyl (such as —CH₂—CH₂—OH, —CH₂—CH(OH)—CH₂—), C₃-C₂₀ cycloalkyl, substituted C₃-C₂₀ cycloalkyl, aryl, substituted aryl and any of these groups containing at least one heteroatom. Examples of cycloalkyl are monocyclic or polycyclic. At least one alkyl substituent should be present attached to nitrogen; if only one alkyl substituent is present on the nitrogen then a C₇ alkyl chain or higher carbon chain is preferred in order to have a boiling point of at least 150° C.; higher boiling points can be achieved by adding additional carbon units where each carbon unit theoretically adds about 23.5° C. to the boiling point. Substituents can also be added to the alkyl chain in the amine derivative and these can consist of alkyl, aryl, cyano, hydroxyl, nitro, carbonylalkyl, hydroxyalkyl, halide and the like. These substituents can be used to increase the bulk or polarity of R₂₀, R₂₁, R₂₂, thereby increasing the boiling point. For instance, hydroxy substituents which are very polar are particularly effective in raising boiling point and consequently 2-aminoethanol in which only 2 carbon atoms are present in structure 3, still has a boiling point of 170° C. Similarly, diethanolamine and triethanol amine have boiling points respectively of 217° C. and 334° C. The groups R₂₀, R₂₁, R₂₂ may also contain within their structure one or more hetero atom groups, for example, O, S, SO, SO₂, —C(═O)—O—, O—C(═O)—O, —OC(═O)—).

In structure 4, which describes a cyclic amine, R₂₄ is selected from hydrogen, C₁-C₂₀ alkyl, substituted C₁-C₂₀ alkyl (such as —CH₂—CH₂—OH, —CH₂—CH(OH)—CH₂—), C₃-C₂₀ cycloalkyl, substituted C₃-C₂₀ cycloalkyl, aryl, substituted aryl and any of these groups containing at least one heteroatom; and R₂₃ is an alkylene spacer (C₁-C₈) which can contain within its structure one of more hetero groups as previously described, or may be functionalized by a substituent or hetero atom groups as previously described. As an example, the cyclic amine 1-propylpiperidine in which R₂₃ is a C₅ spacer and R₂₄ is propyl (C₃) has a boiling point of 152° C. and 1-nonyl-piperidine has a calculated boiling point of 289° C. The cyclic amine 1-butylpyrrolidine where R₂₃ is a C₄ spacer, and R₂₄ is butyl (C₄) has a boiling point of 156° C. Other examples are 1-hexylpyrrolidine; 1-pentyl trimethyleneimine when R₂₃ is a C₃ spacer, and R₂₄ is pentyl (C₅) has a boiling point of about 155° C.; 1-hexylaziridine when R₂₃ is a C₂ spacer and R₂₄ is hexyl(C₆); and 1-aziridineethanol which has R₂₄ as a C₂ spacer and R₂₃ a CH₂CH₂OH has a boiling point of 167.9° C.

In structure 5 which depicts derivatives of quinuclidine in which R₂₅ is hydrogen, C₁-C₂₀ alkyl, substituted C₁-C₂₀ alkyl (such as —CH₂—CH₂—OH, —CH₂—CH(OH)—CH₂—), C₃-C₂₀ cycloalkyl, substituted C₃-C₂₀ cycloalkyl, aryl, substituted aryl and any of these groups containing at least one heteroatom. The R₂₅ group is chosen are bulky or polar enough to ensure that the boiling point is at least 150° C. As described previously, other substitutents and or hetero atom groups as described for structure 3 c an be present and their polarity and size will predicate the boiling point of these derivatives.

Similarly, in structure 6 which depicts derivatives of pyridine in which R₂₆, R₂₇, R₂₈, R₂₉ and R₃₀ are selected from hydrogen, C₁-C₂₀ alkyl, substituted C₁-C₂₀ alkyl (such as —CH₂—CH₂—OH, —CH₂—CH(OH)—CH₂—), C₃-C₂₀ cycloalkyl, substituted C₃-C₂₀ cycloalkyl, aryl, substituted aryl and any of these groups containing at least one heteroatom. As an example, picoline, in which R₂₇ is CH₃ and the other substituents are hydrogen has a boiling point of 145° C. As discussed for structure 3 other substituents or heteroatoms may be present.

Further general examples of the above amino compounds include unsubstituted and substituted trialkylamines, unsubstituted and substituted dialkylamines, and unsubstituted and substituted monoalkylamines, unsubstituted and substituted tricycloalkylamines, unsubstituted and substituted dicycloalkylamines, and unsubstituted and substituted monocycloalkylamines, unsubstituted and substituted monocylcoalkyldialkylamines, unsubstituted and substituted dicycloalkylmonoalkylamines, unsubstituted and substituted monoaryldialkylamines, unsubstituted and substituted diarylmonoalkylamines, unsubstituted and substituted triarylamines, unsubstituted and substituted diarylamines, and unsubstituted and substituted monoarylamines, unsubstituted and substituted triaralkylamines, unsubstituted and substituted diaralkylamines, and unsubstituted and substituted monoaralkylamines, unsubstituted and substituted monoaralkyldialkylamines, unsubstituted and substituted diaralkylmonoalkylamines, unsubstituted and substituted monoarylmonoalkylamines, unsubstituted and substituted monoaralkylmonoalkylamines, unsubstituted and substituted monocycloalkylmonoalkylamines, and unsubstituted and substituted monoarylmonocycloalkylamines and the like.

Specific non restrictive examples of the above amino compounds include tributylamine (Boiling point(Bp) 216° C.), trihexylamine(Bp 263° C.), triisobutylamine(Bp 193° C.), tripentylamine(Bp 240° C.), triheptylamine(Bp 330° C.), N,N-dicyclohexylmethylamine (Bp 265° C.), 2,6-diisopropylaniline (Bp 257° C.), tris[2-(2-methoxyethoxy)ethyl]amine (Bp 330° C.), trioctylamine (Bp 365° C.), tri-n-decylamine(Bp 430° C.), triethanolamine (Bp 334° C.), 1-(2-hydroxyethyl)pyrrolidine (Bp ˜214° C.).

The novel positive bottom photoimageable antireflective coating composition comprises a polymer, a crosslinker and a thermal acid generator. The polymer useful in positive bottom photoimageable antireflective coating compositions is a polymer comprising at least'one group with a hydroxyl and/or a carboxyl group. Polymers that are useful for the present invention have been described in the following patents and patent applications and are incorporated herein: US 2005/0214674 A1, US 2009/0104559 A1, US 2010/0119972 A1, U.S. Ser. No. 12/570,923 filed Sep. 30, 2009 and U.S. Ser. No. 12/576,622 filed Oct. 9, 2010. The polymer comprising at least one hydroxyl and/or a carboxyl group provides alkaline solubility during development and a crosslinking site. A polymer with a latent hydroxyl and/or a carboxyl group which can crosslink is within the scope of the described polymer. One function of the polymer is to provide a good coating quality and another is to enable the underlayer coating to change solubility during the imaging process. The hydroxyl or carboxyl groups in the polymer provide one of the components necessary for the solubility change, where they crosslink with the vinyl ether crosslinker to form an acid cleavable group. Examples of monomers which provide such a unit upon polymerization are without limitations, substituted or unsubstituted vinyl monomers containing a hydroxyl and or carboxyl group, such as acrylic acid, methacrylic acid, vinyl alcohol, hydroxystyrenes, hydroxyethyl methacrylate, hydroxypropyl methacrylate, N-(hydroxymethyl)acrylamide, 4-hydroxyphenyloxy methacrylate, 4-hydroxyphenyloxy acrylate, 5-hydroxynaphthyloxy methacrylate, 5-hydroxynaphthyloxy acrylate, vinyl monomers containing 1,1′,2,2′,3,3′-hexafluoro-2-propanol, although any monomer that makes the polymer alkali soluble and preferably water insoluble, may be used. The polymer may contain a mixture of monomer units containing hydroxyl and/or carboxyl groups. Vinyl monomers containing the 1,1,1,3,3,3-hexafluoro-2-propanol group are represented by structures (7) to (12) and their substituted equivalents.

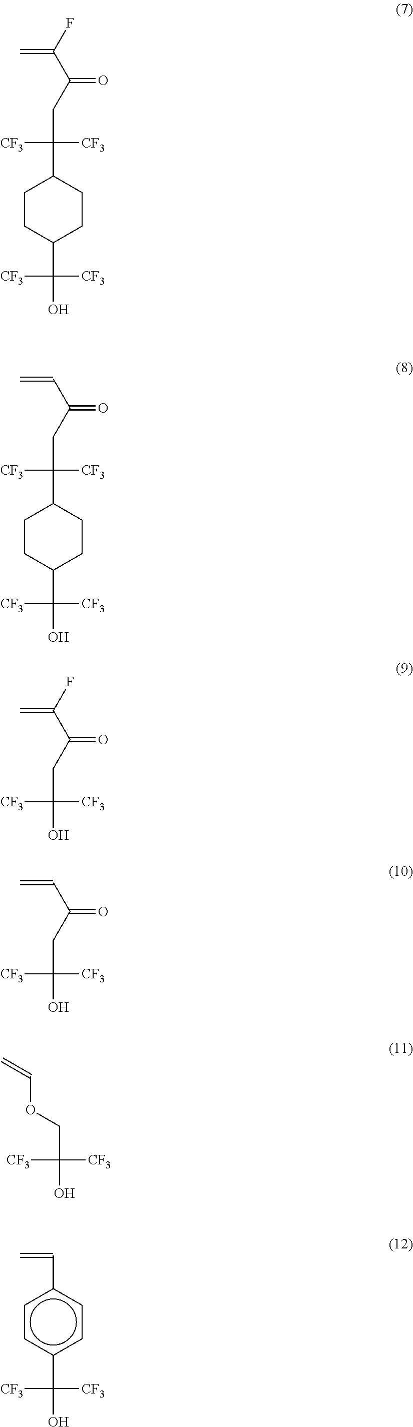

Thus a polymer may be synthesized by polymerizing monomers that contain a hydroxyl or carboxyl group with other types of monomers, such as containing an absorbing chromophore, acid cleavable group, etc. The hydroxyl or carboxyl group and the chromophore and/or the acid cleavable group can be in the same monomeric unit. A skilled artisan will appreciate which chromophores are useful at the exposure or actinic wavelength of interest. Alternatively, the alkali soluble polymer may be reacted with compounds that provide the hydroxyl or carboxyl group and compounds that provide the absorbing chromophore. In the final polymer the mole % of the unit or units containing the hydroxyl or carboxyl group can range from 5 to 95, preferably 10 to 90, and more preferably 20 to 80 and the mole % of the absorbing chromophore unit when present in the final polymer can range from 5 to 95, preferably 10 to 90 more preferably 20 to 80. It is also within the scope of this invention that the hydroxyl or carboxyl group is attached to the absorbing chromophore or that the chromophore is attached to the hydroxyl or carboxyl group, that is, both groups are present in the same unit. As an example the chromophoric groups described previously may have pendant hydroxyl and/or carboxyl groups or that the chromophoric groups and the hydroxyl group and/or carbonyl group are attached to the same group.

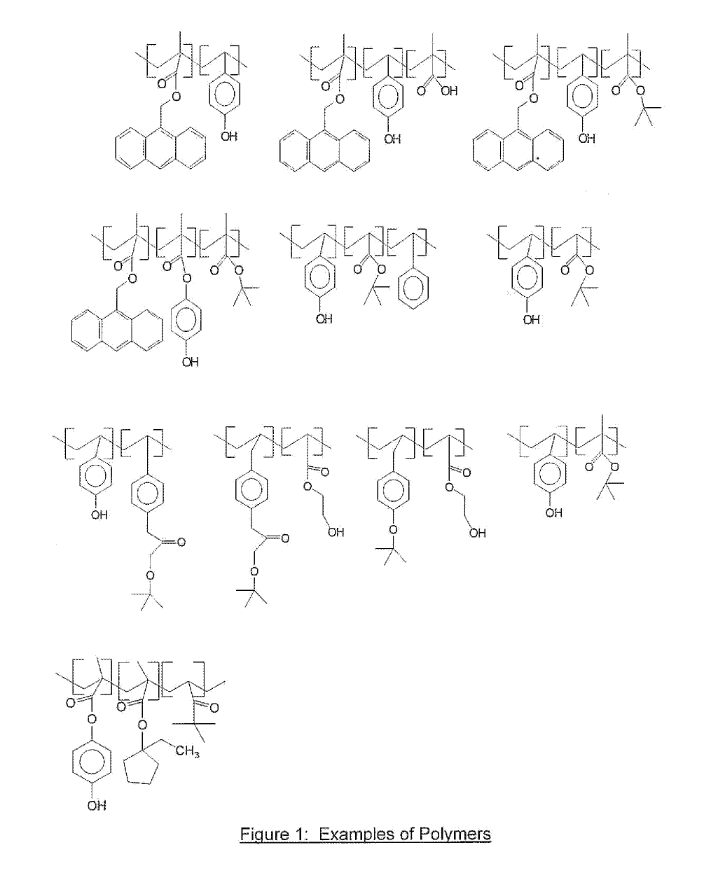

In addition to the unit containing the hydroxyl and/or carboxyl group and the unit containing the absorbing chromophore, the polymer may contain other monomeric units. Examples of the other monomeric unit are —CR₁R₂—CR₃R₄—, where R₁ to R₄ are independently H, (C₁-C₁₀) alkyl, (C₁-C₁₀) alkoxy, nitro, halide, cyano, alkylaryl, alkenyl, dicyanovinyl, SO₂CF₃, COOZ, SO₃Z, COZ, OZ, NZ₂, SZ, SO₂Z, NHCOZ, SO₂NZ₂, where Z is H, or (C₁-C₁₀) alkyl, hetero (C₁-C₁₀) alkyl, (C₁-C₁₀) alkylOCOCH₂COCH₃, or R₂ and R₄ combine to form a cyclic group such as anhydride, pyridine, or pyrollidone, or R₁ to R₃ are independently H, (C₁-C₁₀) alkyl, (C₁-C₁₀) alkoxy and R₄ is a hydrophilic group. Examples of the hydrophilic group, are given here but are not limited to these: O(CH₂)₂OH, O(CH₂)₂O(CH₂)OH, (CH₂)ₙOH (where n=0−4), COO(C₁-C₄) alkyl, COOX and SO₃X (where X is H, ammonium, alkyl ammonium. Other monomers may be methyl methacrylate, butyl methacrylate, hydroxyethyl methacrylate and hydroxypropyl methacrylate. Monomeric units containing acid labile groups may also be used, such as hydroxystyrene, vinyl alcohol, (meth)acrylic acid capped with acid labile groups. Examples of acid labile groups, without limitation, are secondary and tertiary alkyls (up to 20 carbon atoms) with at least one β hydrogen, acetals and ketals, trimethylsilyl, and β-trimethylsilyl substituted alkyls. Representative examples of acid labile groups are tert-butyl, tert-pentyl, isobornyl, 1-alkylcyclohexyl, 1-alkylcyclopentyl, cyclohexyl, 2-alkyl-2-adamantyl, 2-alkyl-2-norbornyl. Other examples of acid labile groups are tetrahydrofuranyl, tetrahydropyranyl, substituted or unsubstituted methoxycarbonyl, trialkylsilylalkyl groups (e.g. CH₂—CH₂Si(CH₃)₃, CH(—CH₂Si(CH₃)₃)₂, CH₂—CH(Si(CH₃)₃)₂ and the like. Examples of the foregoing polymers are given in FIG. 1.

The crosslinking agent of the novel composition includes vinyl ether terminated crosslinking agents. At least 2 vinyl ether groups are present in the crosslinker. In one embodiment the crosslinker may be represented by the general structures (13 and 14):

R¹—(OCH═CH₂)ₘ (13)

R¹—C(O)O—R²—(OCH═CH₂)ₘ (14)

wherein R¹ and R² are independently selected from (C₁-C₃₀) linear, branched or cyclic alkylene, (C₁-C₃₀) linear, substituted or unsubstituted (C₆-C₄₀) arylene, or substituted or unsubstituted (C₇-C₄₀) alicyclic hydrocarbon and mixtures thereof; and m≧2. It is believed that the terminal vinyl ether group reacts with the hydroxyl or carboxyl group of the polymer to give an acid labile acetal linkage. The acid labile linkage is cleaved during the exposure/baking step to form an aqueous alkali soluble polymer. Examples of such vinyl ether terminated crosslinking agents include bis(4-vinyloxy butyl) adipate; bis(4-vinyloxy butyl) succinate; bis(4-vinyloxy butyl) isophathalate; bis(4-vinyloxymethyl cyclohexylmethyl) glutarate; tris(4-vinyloxy butyl) trimellitate; bis(4-vinyloxy methyl cyclohexyl methyl) terephthalate; bis(4-vinyloxy methyl cyclohexyl methyl) isophthalate; bis(4-vinyloxy butyl) (4-methyl-1,3-phenylene) biscarbamate; bis(4-vinyloxy butyl) (methylene di-4,1-phenylene) biscarbamate; and triethyleneglycol divinylether, 1,4-cyclohexanedimentanol divinyl ether, various vinyl ether monomers available under the tradename Vectomer, such as, for example, 4-(vinyloxy)butyl benzoate, bis[4-(vinyloxy)butyl] adipate, bis[4-(vinyloxy)butyl] succinate, 4-(vinyloxymethyl)cyclohexylmethyl benzoate, bis[4-(vinyloxy)butyl] isophthalate, bis[4-(vinyloxymethyl)cyclohexylmethyl] glutarate, tris[4-(vinyloxy)butyl] trimellitate, 4-(vinyloxy)butyl stearate, bis[4-(vinyloxy)butyl] hexanediylbiscarbamate, bis[[4-[(vinyloxy)methyl]cyclohexyl]methyl] terephthalate, bis[[4-[(vinyloxy)methyl]cyclohexyl]methyl] isophthalate, (vinyloxy)butyl] (methylenedi-4,1-phenylene) biscarbamate, bis[4-(vinyloxy)butyl] (4-methyl-1,3-phenylene) biscarbamate, and polymers bearing pendant vinyloxy groups.

When used, the vinyl ether terminated crosslinking agent is added to the underlayer coating composition in a proportion which provides 0.20-2.00 mol equivalents of vinyl ether crosslinking function per reactive group on the polymer, further 0.50-1.50 reactive equivalents per reactive group.

Crosslinking takes place between a polymer containing a hydroxyl and/or carboxyl group and a crosslinking agent in the presence of heat, however, typically reaction times may be long. Thermal acid generators described herein are used to accelerate the crosslinking reaction and are desirable for instances where short curing times are preferred. Thermal acid generators liberate the acid upon heating.

As used herein, alkyl means methyl, ethyl, propyl (n-propyl, i-propyl), butyl (n-butyl, i-butyl, sec-butyl, t-butyl), pentyl (and its isomers), hexyl (and its isomers), heptyl (and its isomers), octyl (and its isomers), and the like. The cycloalkyls include cyclohexyl, menthyl and the like. The alkenyls include allyl, vinyl and the like. The aryl groups include monocyclic or polycyclic rings such as, for example, phenyl, naphthyl and the like. The aralkyl groups include phenylmethyl (i.e., benzyl), phenylethyl (i.e., phenethyl) and the like. Alkylene, cycloalkylene, and arylene mean the same as above for alkyl, cycloalkyl, and aryl except that an additional hydrogen atom has been removed from the alkyl, cycloalkyl or aryl (for example, ethylene, propylene, cyclohexylene, phenylene, etc). The term heteroarylene refers to an arylene having one or more carbon atoms replaced with a heteroatom (for example, S, O, or N).

The solvent for the antireflective coating is chosen such that it can dissolve all the solid components of the antireflective coating, and also can be removed during the bake step so that the resulting coating is not soluble in the coating solvent of the photoresist. Furthermore, to retain the integrity of the antireflective coating is substantially insoluble in the solvent of the top photoresist. Such requirements prevent, or minimize, intermixing of the underlayer with the photoresist layer. Typically propylene glycol monomethyl ether acetate and ethyl lactate are the preferred solvents for the top photoresist. Examples of suitable solvents for the antireflective coating composition are cyclohexanone, cyclopentanone, anisole, 2-heptanone, ethyl lactate, propylene glycol monomethyl ether, butyl acetate, gamma butyroacetate, ethyl cellosolve acetate, methyl cellosolve acetate, methyl 3-methoxypropionate, ethyl pyruvate, 2-methoxybutyl acetate, 2-methoxyethyl ether, but ethyl lactate, propylene glycol monomethyl ether acetate, propylene glycol monomethyl ether or mixtures thereof are preferred. Solvents with a lower degree of toxicity and good coating and solubility properties are generally preferred.

Typical underlayer coating compositions may comprise up to about 15 percent by weight of the solids, preferably less than 8 percent, based on the total weight of the coating composition. The solids may comprise from 0.01 to 25 weight percent of the photoacid generator, 50 to 99 weight percent of polymer, 1 to 50 weight percent of the crosslinking agent and 0.1 to 25 weight percent of the thermal acid generator, based on the total solids content of the antireflective coating composition. When present, the photoacid generator level ranges from about 0.1 to about 20 weight %. Preferably the crosslinking agent ranges from about 5 to about 40 weight percent, more preferably 10 to 35 weight percent. The solid components are dissolved in the solvent, or mixtures of solvents, and filtered to remove impurities. The underlayer composition can optionally contain surfactants, base quencher, and other similar materials. The components of the antireflective coating may also be treated by techniques such as passing through an ion exchange column, filtration, and extraction process, to improve the quality of the product.

Other components may be added to the underlayer composition of the present application in order to enhance the performance of the coating, e.g. lower alcohols, dyes, surface leveling agents, adhesion promoters, antifoaming agents, etc. These additives may be present at up to 30 weight percent level. Other polymers, such as, novolaks, polyhydroxystyrene, polymethylmethacrylate and polyarylates, may be added to the composition, providing the performance is not negatively impacted. Preferably the amount of this polymer is kept below 50 weight % of the total solids of the composition, more preferably 35 weight %, and even more preferably below 20 weight %. Photoacid generators may also be present in the composition.

When the underlayer is absorbing, the absorption parameter (k) of the novel composition ranges from about 0.1 to about 1.0, preferably from about 0.15 to about 0.7 as measured using ellipsometry. The refractive index (n) of the antireflective coating is also optimized. The n and k values can be calculated using an ellipsometer, such as the J. A. Woollam WVASE VU-302 ™ Ellipsometer. The exact values of the optimum ranges for k and n are dependent on the exposure wavelength used and the type of application. Typically for 193 nm the preferred range for k is 0.1 to 0.75, or 0.3 to 0.75; for 248 nm the preferred range for k is 0.15 to 0.8, and for 365 nm the preferred range is from 0.1 to 0.8 or 0.3 to 0.75. The thickness of the underlayer film is less than the thickness of the top photoresist. Preferably the film thickness of the underlayer coating is less than the value of (wavelength of exposure/refractive index), and more preferably it is less than the value of (wavelength of exposure/2 times refractive index), where the refractive index is that of the antireflective coating and can be measured with an ellipsometer. The optimum film thickness of the underlayer coating is determined by the exposure wavelength, refractive indices of the antireflective coating and of the photoresist, absorption characteristics of the top (photoresist) and bottom (underlayer) coatings, and optical characteristics of the substrate. Since the bottom antireflective coating must be removed by exposure and development steps, the optimum film thickness is determined by avoiding the optical nodes where no light absorption is present in the antireflective coating. For 193 nm a film thickness of less than 55 nm is preferred, for 248 nm a film thickness of less than 80 nm is preferred and for 365 nm a film thickness of less than 110 nm is preferred.

The underlayer coating composition is coated on the substrate using techniques well known to those skilled in the art, such as dipping, spin coating or spraying. Various substrates known in the art may be used, such as those that are planar, have topography or have holes. Examples of semiconductor substrates are crystalline and polycrystalline silicon, silicon dioxide, silicon (oxy)nitride, aluminum, aluminum/silicon alloys, and tungsten. In certain cases there can be a buildup of the film at the edges of the substrate, referred to as edge bead. This edge bead, can be removed using a solvent or mixture of solvents using techniques well known to those of ordinary skill in the art. The coating is then cured. The preferred range of temperature is from about 130° C. to about 240° C. for about 30-120 seconds on a hot plate or equivalent heating unit, more preferably from about 180° C. to about 200° C. for 45-90 seconds. The optimum film thickness is determined, as is well known in the art, to be where good lithographic properties are obtained. The cured underlayer coating is insoluble in the solvent of the photoresist and also insoluble at this stage in the alkaline developing solution. The photoresist can then be coated on top of the underlayer coating.

Positive photoresists, which are developed with aqueous alkaline solutions, are useful for the present invention. Positive-working photoresist compositions are exposed image-wise to radiation, those areas of the photoresist composition exposed to the radiation become more soluble to the developer solution (e.g. a rearrangement reaction occurs) while those areas not exposed remain relatively insoluble to the developer solution. Thus, treatment of an exposed positive-working photoresist with the developer causes removal of the exposed areas of the coating and the formation of a positive image in the photoresist coating. Photoresist resolution is defined as the smallest feature which the resist composition can transfer from the photomask to the substrate with a high degree of image edge acuity after exposure and development. In many manufacturing applications today, resist resolution on the order of less than one micron are necessary. In addition, it is almost always desirable that the developed photoresist wall profiles be near vertical relative to the substrate. Such demarcations between developed and undeveloped areas of the resist coating translate into accurate pattern transfer of the mask image onto the substrate. This becomes even more critical as the drive toward miniaturization reduces the critical dimensions on the devices.

Photoresists can be any of the types used in the semiconductor industry, provided the photoactive compound in the photoresist and the antireflective coating absorb at the exposure wavelength used for the imaging process.

To date, there are several major deep ultraviolet (uv) exposure technologies that have provided significant advancement in miniaturization, and these radiation of 248 nm, 193 nm, 157 and 13.5 nm. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure below 200 nm require non-aromatic polymers since aromatics are opaque at this wavelength. U.S. Pat. No. 5,843,624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures. U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference.

Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587, and U.S. Pat. No. 6,849,377) using either metal catalyzed or radical polymerization. Generally, these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (Shun-ichi Kodama et al., Advances in Resist Technology and Processing XIX, Proceedings of SPIE Vol. 4690, pg. 76 (2002); U.S. Pat. No. 6,818,258) or copolymerization of a fluorodiene with an olefin (U.S. Pat. No. 6,916,590). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art.

In positive systems, a film of photoresist is then coated on top of the cured underlayer coating and baked to substantially remove the photoresist solvent. The photoresist and the underlayer coating bilevel layers are then imagewise exposed to actinic radiation. In a subsequent heating step the acid generated during exposure step reacts to de-crosslink or break the acid cleavable bond of the polymer of the antireflective coating composition and thus rendering the exposed region of the antireflective coating alkali soluble in the developing solution. The temperature for the postexposure bake step can range from 40° C. to 200° C. for 30-200 seconds on a hot plate or equivalent heating system, preferably from 80° C. to 160° C. for 40-90 seconds. In some instances, it is possible to avoid the postexposure bake, since for certain chemistries, such as some acetal acid labile linkages, deprotection proceeds at room temperature. The polymer in the exposed regions of the antireflective coating is now soluble in an aqueous alkaline solution. The bilevel system is then developed with an aqueous alkaline developer to remove the photoresist and the antireflective coating, preferably in a single developing step. The developer is preferably an aqueous alkaline solution comprising, for example, tetramethyl ammonium hydroxide. The developer may further comprise additives, such as surfactants, polymers, isopropanol, ethanol, etc. The process of coating and imaging photoresist coatings and antireflective coatings is well known to those skilled in the art and is optimized for the specific type of photoresist and antireflective coating combination used. The imaged bilevel system can then be processed further as required by the manufacturing process of integrated circuits, for example metal deposition and etching.

In a multilayer system, for example, a trilayer system, or process, the trilayer process is where, for example, an organic film is formed on a substrate, an underlayer film is formed on the organic film, and a photoresist film is formed on the underlayer film. An organic film is formed on a substrate as a lower resist film by spin coating method, etc. The organic film may or may not then be crosslinked with heat or acid after application by spin coating method etc. On the organic film is formed the underlayer film, for example that which is disclosed herein, as an intermediate resist film. After applying the underlayer film composition to the organic film by spin-coating etc., an organic solvent is evaporated, and baking is carried out in order to promote crosslinking reaction to prevent the underlayer film from intermixing with an overlying photoresist film. After the underlayer film is formed, the photoresist film is formed thereon as an upper resist film. Spin coating method can be used for forming the photoresist film as with forming the antireflection film. After photoresist film composition is applied by spin-coating method etc., pre-baking is carried out. After that, a pattern circuit area is exposed, and post exposure baking (PEB) and development with a developer are carried out to obtain a resist pattern.

The inventive composition can also be used in a descumming process. The coating composition of the present invention can also be used as a barrier layer when the resin system that is used is transparent (not absorbing) at the wavelength where the composition would be used. When used as a barrier layer, it is placed between a photoresist and a substrate to prevent contamination and defects (e.g., scumming, footing, etc) from occurring.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention. Except where noted, reagents were obtained from Sigma-Aldrich.

### EXAMPLES

Below are the structures associated with the acronyms for each of the monomers employed to make the polymers for the examples below.

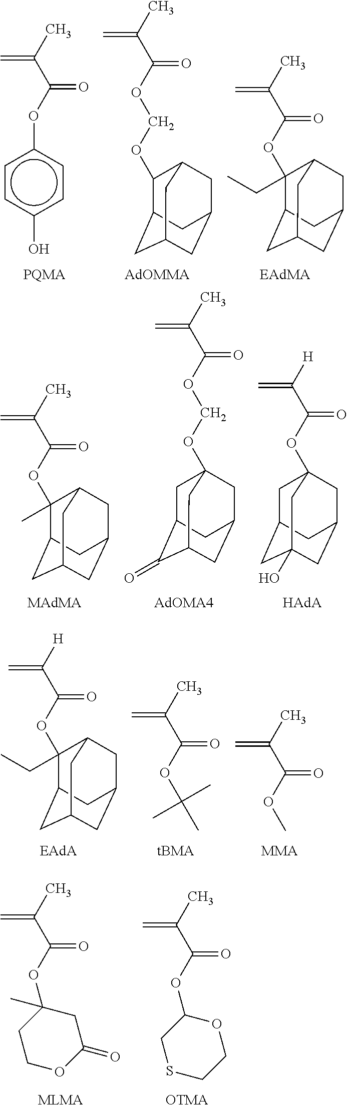

The thermal acid generators were added as the solutions described in Table 2.

Polymers were obtained by radical polymerization using the general procedure outlined in U.S. Ser. No. 12/570,923 filed on Sep. 30, 2009. The number in the parenthesis for each polymer represents the molar feed ratio of monomers used when employing this procedure.

Commercially available 193 nm photoresist is sold by vendors such as Sumitomo Chemical, Tokyo Ohka, Japan Synthetic Rubber, etc.

Table 1 gives a listing of boiling points above 150° C. for different amino compounds, with these as possible amines useful to form thermal acid generators for the present invention. Calc is the calculated value.

Table 1 of Boiling point of amino compounds

| Amine | Amine boiling point | |
|---|---|---|
| Trihexylamine | 263° | C. |
| Tributylamine | 216° | C. |
| Triisobutylamine | 193° | C. |
| Tripentylamine | 240° | C. |
| Triheptylamine | 330° | C. |
| N,N-dicyclohexylmethylamine | 265° | C. |
| 2,6-Diisopropylaniline | 257° | C. |
| Tris[2-(2- | 330° | C. |
| methoxyethoxy)ethyl]amine | | |
| Trioctylamine | 365° | C. |
| Tri-n-decylamine | 430° | C. |
| Triethanolamine | 335° | C. |
| 1-(2-hydroxyethyl)pyrrolidine | 214° | C. |
| Heptyl amine | 155° | C. |
| dibutyl amine | 159° | C. |
| tridodecyl | 450° | C. |
| 1-propyl piperidine | 152° | C. |
| 1-butyl piperidine | 175° | C. |
| 1-pentyl piperidine | 198° | C. calc |
| 1-hexyl piperidine | 219° C., 220° C. calc | |
| 1-heptyl piperidine | 243° | C. calc |
| 1-octyl piperadine | 266° | C. calc |
| 1-nonyl piperadine | 289° | C. calc |
| 1-butyl pyrrolidine | 156° C., 155° C. calc | |
| 1-pentyl pyrrolidine | 181° | C. calc |
| 1-hexyl pyrrolidine | 206° | C. calc |
| hexamethyleneimine | 138° | C. |
| 1-pentyltrimethyleneimine | 155° | C. |
| 1-hexyltrimethyleneimine | 180° | C. |
| 1-pentyltrimethyleneimine | 167.9° | C. |
| 2-aminoethanol | 170° | C. |
| diethanolamine | 217° | C. |

### Synthesis Example 1

1.04 g of malonic acid was dissolved in 62.68 g of propylene glycol monomethylether (PGME). To this a malonic acid solution, 5.928 g of trihexylamine was added and mixed. The solution was heated at 40° C. under reduced pressure using a rotary evaporator and the product was isolated. H-NMR spectrum showed N⁺CH₂ proton at 3.8 ppm, O₂CCH₂CCO₂″ proton at 3.9 ppm. Proton of free carboxyl group was not observed and formation of di-carboxylic acid salt was confirmed.

Table 2 lists examples 1-15 which were all the salts which were made as stock solutions in PGME and used in the formulation examples. These were reacted in the same manner as shown above, however, leaving the materials in PGME as stock solutions to be used in the above described formulation examples.

TABLE 2
Thermal Acid generator Solutions

| | | | Amine | |
|---|---|---|---|---|
| Synth | Carboxylic | | boiling | |
| Example | acid | Amine | point | Solvent |
| 1 | Malonic acid | Trihexylamine (5.93 g) | 263° C. | PGME (62.48) |
| | (1.04 g) | | | |
| 2 | Malonic acid | Tributylamine (4.08 g) | 216° C. | PGME (46.06 g) |
| | (1.04 g) | | | |
| 3 | Malonic acid | Triisobutylamine] (2.04 g) | 193° C. | PGME (21.18 g) |
| | (0.52 g) | | | |
| 4 | Malonic acid | Tripentylamine (2.5 g) | 240° C. | PGME (24.9 g) |
| | (0.52 g) | | | |
| 5 | Malonic acid | Triheptylamine (3.65 g) | 330° C. | PGME (34.1 g) |
| | (0.52 g) | | | |
| 6 | Malonic acid | N,N- | 265° C. | PGME (48.04 g) |
| | (1.04 g) | dicyclohexylmethylamine | | |
| | | (4.3 g) | | |
| 7 | Malonic acid | 2,6-Diisopropylaniline | 257° C. | PGME (44.46 g) |
| | (1.04 g) | (1.77 g) | | |
| 8 | Malonic acid | Tris[2-(2- | 330° C. | PGME (36.7 g) |
| | (0.52 g) | methoxyethoxy)ethyl]amine | | |
| | | (3.557 g) | | |
| 9 | Malonic acid | Triethyamine (3.373 g) | 89° C. | PGME (51.07 g) |
| | (1.73 g) | | | |
| 10 | Malonic acid | Trioctylamine (3.89 g) | 365° C. | PGME (40.57 g) |
| | (0.52 g) | | | |
| 11 | Heptanoic | Trioctylamine (3.89 g) | 365° C. | PGME (43.54 g) |
| | acid (1.3 g) | | | |
| 12 | Malonic acid | Tri-n-decylamine (4.82 g) | 430° C. | PGME (43.65 g) |
| | (0.52 g) | | | |
| 13 | Malonic acid | Triethanolamine (3.28 g) | 335° C. | PGME (38.91 g) |
| | (1.04 g) | | | |
| 14 | 2- | Triethanolamine (1.502 g) | 335° C. | PGME (22.79 g) |
| | Hydroxyisobutyric | | | |
| | acid | | | |
| | (1.04 g) | | | |
| 15 | Malonic acid | 1-(2- | 214° C. | PGME (32.17 g) |
| | (1.04 g) | hydroxyethyl)pyrrolidine | | |
| | | (2.53 g) | | |

### Example 1

An underlayer solution was prepared using the following components: PQMA/AdOMMA/EAdMA(55/20/25) terpolymer (0.1265 g), tris(vinyloxybutyl)cyclohexane 1,2,4-tricarboxylate (0.038 g), bis(tributylammonium)malonate (0.036 g) and bis[tris(4-vinyloxyethoxyphenyl)sulfonium]perfluorobutanedisulfonate (00027 g), 10.27 g of propyleneglycol monomethylether, 4.38 g of propyleneglycol monomethylether acetate and 0.185 g of γ-valerolactone and formed, a photosensitive antireflective composition. The bis(tributylammonium)malonate was made by adding tributylamine to in a malonic acid/PGME solution. The solution was filtered through a 0.2 μm micron filter.

The underlayer solution was coated on a primed silicon wafer and heated on a hotplate at 205° C. for 60 seconds to give a film thickness of 40 nm. The B.A.R.C. wafer was coated with a commercially available 193 nm photoresist and heated on a hotplate for 100° C. for 60 seconds to give a film thickness of 110 nm. The coated wafer was exposed using Nikon 306D 193 nm scanner for imagewise exposure. The exposed wafer was then post exposure baked for 60 seconds at 100° C. and followed with a 15-second puddle development at 23° C. using of AZ® 300 MIF Developer. Using a Scanning Electron Microscope (SEM), development of 70 nm photoresist/underlayer lines (1:1) were obtained with clean pattern for photoresist and clean trench spaces with complete opening of the underlayer film at a dose of 46.5 mJ/cm² and with good patterns upto 54 mJ/cm².

### Example 2

The underlayer solution was prepared using the following components PQMA/AdOMMA/EAdMA (55/20/25) terpolymer (0.1265 g), tris(vinyloxybutyl)cyclohexane 1,2,4-tricarboxylate (0.038 g), bis(triisobutylammonium)malonate (0.036 g) and bis[tris(4-vinyloxyethoxyphenyl)sulfonium]perfluorobutanedisulfonate (0.0027 g), 10.23 g of propyleneglycol monomethylether, 4.38 g of propyleneglycol monomethylether acetate and 0.185 g of γ-valerolactone and formed a photosensitive antireflective composition. The solution was filtered through a 0.2 μm micron filter.

The underlayer solution was coated on a primed silicon wafer, and processed as described in Example 1. Using a scanning electron microscope (SEM), 70 nm photoresist/underlayer lines (1:1) were obtained with clean pattern for photoresist and clean trench spaces with complete opening of the underlayer at a dose of 46.5 mJ/cm² and with good patterns upto 52.5 mJ/cm².

### Example 3

The underlayer solution was prepared using the following components PQMA/AdOMMA/EAdMA(55/20/25) terpolymer (0.1191 g), tris(vinyloxybutyl)cyclohexane 1,2,4-tricarboxylate (0.036 g), bis(trihexylammonium)malonate (0.045 g) and bis[tris(4-vinyloxyethoxyphenyl)sulfonium]perfluorobutanedisulfonate (0.0025 g) 10.23 g of propyleneglycol monomethylether, 4.38 g of propyleneglycol monomethylether acetate and 0.185 g of γ-valerolactone forming a photosensitive antireflective composition. The solution was filtered through a 0.2 μm micron filter.

The underlayer solution was coated on a primed silicon wafer, and processed as described in Example 1. Using a Scanning. Electron Microscope (SEM), 70 nm photoresist/underlayer lines (1:1) were obtained with clean pattern for photoresist and clean trench spaces with complete opening of the underlayer at a dose of 46.5 mJ/cm² and with good patterns upto 55.5 mJ/cm².

### Example 4

The underlayer solution was prepared using the following components PQMA/AdOMMA/EAdMA (55/20/25) terpolymer (0.123 g), tris(vinyloxybutyl)cyclohexane 1,2,4-tricarboxylate (0.037 g), bis(tripentylammonium)malonate (0.041 g) and bis[tris(4-vinyloxyethoxyphenyl)sulfonium]perfluorobutanedisulfonate (0.0026 g) 10.23 g of propyleneglycol monomethylether, 4.38 g of propyleneglycol monomethylether acetate and 0.185 g of γ-valerolactone forming a photosensitive antireflective composition. The solution was filtered through a 0.2 μm micron filter.

The underlayer solution was coated, on a primed silicon wafer, and processed as described in Example 1. Using a Scanning Electron Microscope (SEM), 70 nm photoresist/underlayer lines (1:1) were obtained with clean pattern for photoresist and clean trench spaces with complete opening of the underlayer at a dose of 46.5 mJ/cm² and with good patterns upto 55.5 mJ/cm².

### Example 5

The underlayer solution was prepared using the following components PQMA/AdOMMA/EAdMA (55/20/25) terpolymer (0.114 g), tris(vinyloxybutyl)cyclohexane 1,2,4-tricarboxylate (0.034 g), bis(triheptylammonium)malonate (0.052 g) and bis[tris(4-vinyloxyethoxyphenyl)sulfonium]perfluorobutanedisulfonate (0.0024 g) 10.23 g of propyleneglycol monomethylether, 4.38 g of propyleneglycol monomethylether acetate and 0.185 g of γ-valerolactone forming a photosensitive antireflective composition. The solution was filtered through a 0.2 μm micron filter.

The underlayer solution was coated on a primed silicon wafer, and processed as described in Example 1. Using a Scanning Electron Microscope (SEM), 70 nm photoresist/underlayer lines (1:1) were obtained with clean pattern for photoresist and clean trench spaces with complete opening of the underlayer at a dose of 46.5 mJ/cm² and with good patterns upto 55.5 mJ/cm².

### Example 6

The underlayer solution was prepared using the following components PQMA/AdOMMA/EAdMA (55/20/25) terpolymer (0.126 g), tris(vinyloxybutyl)cyclohexane 1,2,4-tricarboxylate (0.037 g), bis(N,N-dicyclohexylmethylammonium)malonate (0.037 g) and bis[tris(4-vinyloxyethoxyphenyl)sulfonium]perfluorobutanedisulfonate (0.0026 g), 10.23 g of propyleneglycol monomethylether, 4.38 g of propyleneglycol monomethylether acetate and 0.29 g of γ-valerolactone forming a photosensitive antireflective composition. The solution was filtered through a 0.2 μm micron filter.

The underlayer solution was coated on a primed silicon wafer, and processed as described in Example 1. Using a Scanning Electron Microscope (SEM), 70 nm photoresist/B.A.R.C. Lines (1:1) were obtained with clean pattern for photoresist and clean trench spaces with complete opening of the underlayer at a dose of 46.5 mJ/cm² and with good patterns upto 54 mJ/cm².

### Example 7

This solution was prepared using the following components PQMA/AdOMMA/EAdMA (55/20/25) terpolymer (0.115 g), tris(vinyloxybutyl)cyclohexane 1,2,4-tricarboxylate (0.034 g), bis([tris2-(2-methoxyethoxy)ethyl]ammonium) malonate (0.051 g) and bis[tris(4-vinyloxyethoxyphenyl)sulfonium]perfluorobutanedisulfonate (0.0024 g), 10.23 g of propyleneglycol monomethylether, 4.38 g of propyleneglycol monomethylether acetate and 0.19 g of γ-valerolactone forming a photosensitive antireflective composition. The solution was filtered through a 0.2 μm micron filter.

The underlayer solution was coated on a primed silicon wafer, and processed as described in Example 1. Using a Scanning Electron Microscope (SEM), 70 nm photoresist/underlayer lines (1:1) were obtained with clean pattern for photoresist and clean trench spaces with complete opening of the underlayer at a dose of 46.5 mJ/cm² and with good patterns upto 55.5 mJ/cm².

### Example 8

The underlayer solution was prepared using the following components PQMA/AdOMMA/EAdMA (55/20/25) terpolymer (0.127 g), tris(vinyloxybutyl)cyclohexane 1,2,4-tricarboxylate (0.038 g), bis(2,6-diisopropylanilinium)malonate (0.035 g) and bis[tris(4-vinyloxyethoxyphenyl)sulfonium]perfluorobutanedisulfonate (0.0027 g), 10.23 g of propyleneglycol monomethylether, 4.38 g of propyleneglycol monomethylether acetate and 0.19 g of γ-valerolactone forming a photosensitive antireflective composition. The solution was filtered through a 0.2 μm micron filter.

The underlayer solution was coated on a primed silicon wafer, and processed as described in Example 1. Using a Scanning Electron Microscope (SEM), 70 nm photoresist/underlayer lines (1:1) were obtained with clean pattern for photoresist and clean trench spaces with complete opening of the underlayer at a dose of 46.5 mJ/cm² and with good patterns upto 54 mJ/cm².

### Example 9

This solution was prepared using the following components PQMA/AdOMMA (75/25) polymer (0.068 g), tris(vinyloxybutyl)cyclohexane 1,2,4-tricarboxylate (0.0251 g), bis(trihexylammonium)malonate (0.0305 g) and bis[tris(4-vinyloxyethoxyphenyl)sulfonium]perfluorobutanedisulfonate (0.0014 g) were dissolved in mixture of 6.77 g of propyleneglycol monomethylether, 2.96 g of propyleneglycol monomethylether acetate and 0.142 g of γ-valerolactone forming a photosensitive antireflective composition. The solution was filtered through a 0.2 μm micron filter.

The underlayer solution was coated on a primed silicon wafer, and processed as described in Example 1. Using a Scanning Electron Microscope (SEM), 70 nm photoresist/underlayer lines (1:1) were obtained with clean pattern for photoresist and clean trench spaces with complete opening of the underlayer at a dose of 29.5 mJ/cm² and with good patterns upto 35.5 mJ/cm².

### Example 10

This solution was prepared using the following components PQMA/MAdMA (60/40) polymer (1.783 g), tris(vinyloxybutyl)cyclohexane 1,2,4-tricarboxylate (0.517 g), bis(trihexylammonium)malonate (0.6622 g) and bis[tris(4-vinyloxyethoxyphenyl)sulfonium]perfluorobutanedisulfonate (0.0375 g), 100.695 g of propyleneglycol monomethylether, 44.1 g of propyleneglycol monomethylether acetate and 2.205 g of γ-valerolactone forming a photosensitive antireflective composition. The solution was filtered through a 0.2 μm micron filter.

The underlayer solution was coated on a primed silicon wafer and heated on a hotplate at 205° C. for 60 seconds to give a film thickness of 400 Å. The wafer with the underlayer was coated with 193 nm photoresist heated on a hotplate for 100° C. for 60 seconds to give a film thickness of 210 nm. The coated wafer was exposed using Nikon 306D 193 nm scanner for imagewise exposure. The exposed wafer was then post exposure baked for 60 seconds at 100° C. and followed with a 30-second puddle development at 23° C. using of AZ® 300 MIF Developer. Using a Scanning Electron Microscope (SEM), 180 nm photoresist/underlayer lines (1:1) were obtained with clean profile for photoresist and clean trench spaces with complete underlayer opening at a dose of 19.5 mJ/cm².

### Example 11

The underlayer solution was prepared using the following components PQMA/MAdMA/MAA (55/22.5/22.5) polymer (0.1635 g), tris(vinyloxybutyl)cyclohexane 1,2,4-tricarboxylate (0.0587 g), bis(trihexylammonium)malonate (0.0744 g) and bis[tris(4-vinyloxyethoxyphenyl)sulfonium]perfluorobutanedisulfonate (0.0034 g), 20.3445 g of propyleneglycol monomethylether, 8.91 g of propyleneglycol monomethylether acetate and 0.4455 g of γ-valerolactone to form a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/underlayer Lines (1:1) were obtained with clean profile for resist and clean trench spaces with complete underlayer opening at a dose of 19.5 mJ/cm².

### Example 12

This solution was prepared using the following components PQMA/EAdMA (50/50) polymer (0.5408 g), tris(vinyloxybutyl)cyclohexane 1,2,4-tricarboxylate (0.1524 g), bis(trihexylammonium)malonate (0.1954 g), bis[tris(4-vinyloxyethoxyphenyl)sulfonium]perfluorobutanedisulfonate (0.0114 g), 61.033 g of propyleneglycol monomethylether, 26.73 g of propyleneglycol monomethylether acetate and 1.3365 g of γ-valerolactone forming a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/underlayer lines (1:1) were obtained with clean profile for photoresist and clean trench spaces with complete opening of the underlayer at a dose of 19.5 mJ/cm².

### Example 13

This solution was prepared using the following components PQMA/EAdMA (60/40) polymer (0.5077 g), tris(vinyloxybutyl)cyclohexane 1,2,4-tricarboxylate (0.1679 g), bis(trihexylammonium)malonate (0.2137 g), bis[tris(4-vinyloxyethoxyphenyl)sulfonium]perfluorobutanedisulfonate (0.0107 g), 61.033 g of propyleneglycol monomethylether, 26.73 g of propyleneglycol monomethylether acetate and 1.3365 g of γ-valerolactone to form a photosensitive antireflective composition. The solution was filtered through a 0.2 μm micron filter.

The underlayer solution was coated on a primed silicon wafer and heated on a hotplate at 205° C. for 60 seconds to give a film thickness of 400 Å. The wafer with the underlayer was coated with 193 nm photoresist and heated on a hotplate for 100° C. for 60 seconds to give a film thickness of 210 nm. The coated wafer was exposed using Nikon 306D 193 nm scanner for imagewise exposure. The exposed wafer was then post exposure baked for 60 seconds at 100° C. and followed with a 30-second puddle development at 23° C. using of AZ® 300 MIF Developer. Using a Scanning Electron Microscope (SEM), 180 nm photoresist/underlayer lines (1:1) were obtained with clean profile for resist and clean trench spaces with complete opening of the underlayer at a dose of 19.5 mJ/cm².

### Example 14

The underlayer solution was prepared from the stock solutions as described above consisted of the following components PQMA/MAdMA/OTMA (60/20/20) polymer (0.5113 g), tris(vinyloxybutyl)cyclohexane 1,2,4-tricarboxylate (0.1663 g), bis(trihexylammonium)malonate (0.2117 g) and bis[tris(4-vinyloxyethoxyphenyl)sulfonium]perfluorobutanedisulfonate (0.0108 g), 61.033 g of propyleneglycol monomethylether, 26.73 g of propyleneglycol monomethylether acetate and 1.3365 g of γ-valerolactone forming a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/underlayer lines (1:1) were obtained with clean profile for photoresist and clean trench spaces with complete opening of the underlayer at a dose of 19.5 mJ/cm².

### Example 15

This solution was using the following components PQMA/AdOMMA/MLMA (60/20/20) polymer (0.4709 g), tris(vinyloxybutyl)cyclohexane 1,2,4-tricarboxylate (0.1526 g), bis(trihexylammonium)malonate (0.1944 g) and bis[tris(4-vinyloxyethoxyphenyl)sulfonium]perfluorobutanedisulfonate (0.0099 g), 56.13 g of propyleneglycol monomethylether, 24.585 g of propyleneglycol monomethylether acetate and 1.2293 g of γ-valerolactone forming a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/underlayer lines (1:1) were obtained with clean profile for photoresist and clean trench spaces with complete opening of the underlayer at a dose of 19.5 mJ/cm².

### Example 16

The underlayer solution was prepared from the stock solutions as described above and consisted of the following components PQMA/MAdMA/HadA (70/20/10) polymer (0.4911 g), tris(vinyloxybutyl)cyclohexane 1,2,4-tricarboxylate (0.1757 g), bis(trihexylammonium)malonate (0.2229 g) and bis[tris(4-vinyloxyethoxyphenyl)sulfonium]perfluorobutanedisulfonate (0.0103 g) were dissolved in mixture of 61.033 g of propyleneglycol monomethylether, 26.73 g of propyleneglycol monomethylether acetate and 1.3365 g of γ-valerolactone to form a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/B.A.R.C. Lines (1:1) were obtained with clean profile for photoresist and clean trench spaces with complete opening of the underlayer at a dose of 19.5 mJ/cm².

### Example 17

The underlayer solution was prepared from the stock solutions as described above and consisted of the following components PQMA/AdOMMA/EAdA (55/20/25) polymer (0.5211 g), tris(vinyloxybutyl)cyclohexane 1,2,4-tricarboxylate (0.1616 g), bis(trihexylammonium)malonate (0.2063 g) and bis[tris(4-vinyloxyethoxyphenyl)sulfonium]perfluorobutanedisulfonate (0.0110 g), 61.033 g of propyleneglycol monomethylether, 26.73 g of propyleneglycol monomethylether acetate and 1.3365 g of γ-valerolactone forming a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/underlayer lines (1:1) were obtained with clean profile for photoresist and clean trench spaces with complete opening of the underlayer at a dose of 19.5 mJ/cm².

### Example 18

The underlayer solution was prepared from the stock solutions as described above and consisted of the following components. PQMA/tBMA (65/35) polymer (0.417 g), tris(vinyloxybutyl)cyclohexane 1,2,4-tricarboxylate (0210 g), bis(trihexylammonium)malonate (0.264 g) and bis[tris(4-vinyloxyethoxyphenyl)sulfonium]perfluorobutanedisulfonate (0.0088 g), 61.03 g of propyleneglycol monomethylether, 26.73 g of propyleneglycol monomethylether acetate and 1.337 g of γ-valerolactone to form a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/underlayer trench (1:5) were obtained with completely opening trench spaces of the underlayer at an exposure dose of 16.5 mJ/cm².

### Example 19

The underlayer solution was prepared from the stock solutions as described above and consisted of the following components PQMA/MMA (55/45) polymer (0.423 g), tris(vinyloxybutyl)cyclohexane 1,2,4-tricarboxylate (0.208 g), bis(trihexylammonium)malonate (0.260 g) and bis[tris(4-vinylxyethoxyphenyl)sulfonium]perfluorobutanedisulfonate (0.0089 g), 61.03 g of propyleneglycol monomethylether, 26.73 g of propyleneglycol monomethylether acetate and 1.337 g of γ-valerolactone forming a photosensitive antireflective composition. The solution was filtered through a 0.2 μm micron filter.

The underlayer solution was coated on a primed silicon wafer, and processed as described in Example 10. Using a Scanning Electron Microscope (SEM), 180 nm photoresist/underlayer trench (1:5) were obtained with completely opening trench spaces of B.A.R.C. at an exposure dose of 16.5 mJ/cm².

### Example 20

The underlayer solution was prepared from the stock solutions as described above and consisted of the following components PQMA/MAdMA (60/40) polymer (0.1775 g), tris(vinyloxybutyl)cyclohexane 1,2,4-tricarboxylate (0.0472 g), bis(trioctylammonium)malonate (0.0725 g) and bis(triphenylsulfonium)perfluorobutanedisulfonate (0.0028 g), 24.419 g of propyleneglycol monomethylether and 0.2805 g of γ-valerolactone to form a photosensitive antireflective composition. The solution was filtered through a 0.2 μm micron filter.

The underlayer solution was coated on a primed silicon wafer, and processed as described in Example 1. Using a scanning electron microscope (SEM), 90 nm photoresist/underlayer trenches (1:1) were obtained with clean profile for resist and clean trench spaces with complete opening of the underlayer at a dose of 35.5 mJ/cm².

### Example 21

The underlayer solution was prepared from the stock solutions as described above and consisted of the following components PQMA/MAdMA (50/50) polymer (0.1696 g), tris(vinyloxybutyl)cyclohexane 1,2,4-tricarboxylate (0.0451 g), trioctylammonium heptanoate (0.0826 g) and bis(triphenylsulfonium)perfluorobutanedisulfonate (0.0027 g), 24.43 g of propyleneglycol monomethylether and 0.268 g of γ-valerolactone to form a photosensitive antireflective composition. The solution was filtered through a 0.2 μm micron filter.

The underlayer solution was coated on a primed silicon wafer, and processed as described in Example 1. Using a scanning electron microscope (SEM), 90 nm photoresist/underlayer trenches (1:1) were obtained with clean profile for resist and clean trench spaces with complete opening underlayer at an dose of 35.5 mJ/cm².

### Example 22

The underlayer solution was prepared from the stock solutions as described above and consisted of the following components PQMA/AdOMA4 (83/17) polymer (0.1163 g), tris(vinyloxybutyl)cyclohexane 1,2,4-tricarboxylate (0.0488 g), bis(tri-n-decylammonium)malonate (0.0930 g) and bis[tris(4-vinyloxyethoxyphenyl)sulfonium]perfluorobutanedisulfonate (0.0020 g) were dissolved in mixture of 13.64 g of propyleneglycol monomethylether, 5.84 g of propyleneglycol monomethylether acetate and 0.247 g of γ-valerolactone to form a photosensitive antireflective composition. The solution was filtered through a 0.2 μm micron filter.

The underlayer solution was coated on a primed silicon wafer, and processed as described in Example 1. Using a scanning electron microscope (SEM), 80 mm photoresist/underlayer lines (1:1) were obtained with clean line for resist and clean trench spaces for the underlayer at a dose of 36.5 mJ/cm².

### Example 23

The underlayer solution was prepared from the stock solutions as described above and consisted of the following components PQMA/MAdMA (50/50) polymer (0.202 g), tris(vinyloxybutyl)cyclohexane 1,2,4-tricarboxylate (0.0538 g), bis(triethanolaminium)malonate (0.0409 g) and bis(triphenylsulfonium)perfluorobutanedisulfonate (0.0032 g), 24.38 g of propyleneglycol monomethylether and 0.319 g of γ-valerolactone forming a photosensitive antireflective composition. The solution was filtered through a 0.2 μm micron filter.

The underlayer solution was coated on a primed silicon wafer, and processed as described in Example 1. Using a scanning electron microscope (SEM), 90 nm photoresist/underlayer lines (1:5) were obtained at an exposure dose of 34 mJ/cm².

### Example 24

The solution was prepared from the stock solutions as described above and consisted of the following components PQMA/MAdMA (50/50) polymer (0.195 g), tris(vinyloxybutyl)cyclohexane 1,2,4-tricarboxylate (0.0519 g), triethanolaminium 2-hydroxyisobutyrate (0.0498 g) and bis(triphenylsulfonium)perfluorobutanedisulfonate (0.0031 g), 24.39 g of propyleneglycol monomethylether and 0.308 g of γ-valerolactone forming a photosensitive antireflective composition. The solution was filtered through a 0.2 μm micron filter.

The underlayer solution was coated on a primed silicon wafer, and processed as described in Example 1. Using a scanning electron microscope (SEM), 90 nm photoresist/underlayer lines (1:5) were obtained at a dose of 35.5 mJ/cm².

### Example 25

The underlayer solution was prepared from the stock solutions as described above and consisted of the following components PQMA/MAdMA (80/20) polymer (0.186 g), tris(vinyloxybutyl)cyclohexane 1,2,4-tricarboxylate (0.0671 g), bis[1-(2-hydroxyethyl)pyrrolidinium]malonate (0.0425 g) and bis[tris(4-vinyloxyethoxyphenyl)sulfonium]perfluorobutanedisulfonate (0.0039 g), 24.31 g of propyleneglycol monomethylether and 0.388 g of γ-valerolactone forming a photosensitive antireflective composition. The solution was filtered through a 0.2 μm micron filter.

The underlayer solution was coated on a primed silicon wafer, and processed as described in Example 1. Using a scanning electron microscope (SEM), 90 nm photoresist/underlayer lines (1:5) were obtained at a dose of 35.5 mJ/cm².

### Comparative Example 1

This solution was prepared from the stock solutions as described above and consisted of the following components PQMA/AdOMMA/EAdMA (55/20/25) terpolymer (0.132 g), tris(vinyloxybutyl)cyclohexane 1,2,4-tricarboxylate (0.039 g), bis(triethylammonium)malonate (0.029 g) and bis[tris(4-vinyloxyethoxyphenyl)sulfonium]perfluorobutanedisulfonate (0.0029 g), 10.23 g of propyleneglycol monomethylether, 4.38 g of propyleneglycol monomethylether acetate and 0.185 g of γ-valerolactone forming a photosensitive antireflective composition. The solution was filtered through a 0.2 μm micron filter.

The underlayer solution was coated on a primed silicon wafer, and processed as described in Example 1. Using a Scanning Electron Microscope (SEM), patterns were inspected, but 70 nm photoresist/underlayer lines (1:1) were not obtained due to pattern collapse.

### Comparative Example 2

The underlayer solution was prepared from the stock solutions as described above and consisted of the following components PQMA/AdOMMA (75/25) polymer (0.973 g), tris(vinyloxybutyl)cyclohexane 1,2,4-tricarboxylate (0.359 g), bis(triethylammonium)malonate (0.207 g) and bis[tris(4-vinyloxyethoxyphenyl)sulfonium]perfluorobutanedisulfonate (0.0205 g) were dissolved in mixture of 80.88 g of propyleneglycol monomethylether, 35.53 g of propyleneglycol monomethylether acetate and 2.027 g of γ-valerolactone forming a photosensitive antireflective composition. The solution was filtered through a 0.2 μm micron filter.

The underlayer solution was coated on a primed silicon wafer, and processed as described in Example 1. Using a Scanning Electron Microscope (SEM), patterns were inspected, but 80 nm photoresist/underlayer lines (1:1) were not obtained due to pattern collapse.

### Comparative Example 3

This solution was prepared from the stock solutions as described above and consisted of the following components PQMA/MAdMA (60/40) polymer (0.242 g), tris(vinyloxybutyl)cyclohexane 1,2,4-tricarboxylate (0.070 g), bis(triethylammonium)malonate (0.0428 g) and bis[tris(4-vinyloxyethoxyphenyl)sulfonium]perfluorobutanedisulfonate (0.051 g), 13.453 g of propyleneglycol monomethylether, 5.892 g of propyleneglycol monomethylether acetate and 0.295 g of γ-valerolactone forming a photosensitive antireflective composition. The solution was filtered through a 0.2 μm micron filter.

The underlayer solution was coated on a primed silicon wafer, and processed as described in Example 10. Using a Scanning Electron Microscope (SEM), patterns were inspected, but 180 nm photoresist/underlayer lines (1:1) were obtained, but photoresist bottom size was smaller than photoresist top size and the pattern profile was not acceptable.

The foregoing description of the invention illustrates and describes the present invention. Additionally, the disclosure shows and describes only certain embodiments of the invention but, as mentioned above, it is to be understood that the invention is capable of use in various other combinations, modifications, and environments and is capable of changes or modifications within the scope of the inventive concept as expressed herein, commensurate with the above teachings or the skill or knowledge of the relevant art.

1. An photoimageable underlayer composition comprising a polymer, a crosslinker, and a thermal acid generator comprising a salt of a mono or polycarboxylic acid and an amine, where the amine has a boiling point of at least 150° C.

2. The photoimageable underlayer composition of claim 1, further comprising a photoacid generator.

3. The photoimageable underlayer composition of claim 1, where the amine has a boiling point of at least 180° C.

4. The photoimageable underlayer composition of claim 1, where the amine has a boiling point of at least 210° C.

5. The photoimageable underlayer composition of claim 1, where the amine has a boiling point of at least 250° C.

6. The composition of claim 1, the thermal acid generator is selected from structure 1 and structure 2, 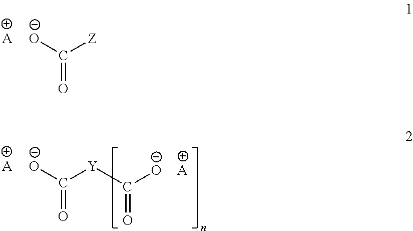
where, A is an amino cation, Z is chosen from the group selected from (C₁-C₂₀)alkyl, substituted (C₁-C₂₀)alkyl, (C₂-C₂₀)alkenyl, substituted (C₂-C₂₀)alkynyl, substituted (C₁-C₂₀) alkyl containing at least one heteroatom, substituted (C₂-C₂₀) alkenyl containing at least one heteroatom, substituted alkynyl (C₂-C₂₀) containing at least one heteroatom, (C₆-C₂₀)aryl, and substituted (C₆-C₂₀)aryl; and the connecting group Y can be selected from a direct valence bond, C₁-C₈ alkylene, substituted C₁-C₈ alkylene, C₁-C₈ alkylene containing one or more hetero atom groups, substituted C₁-C₈ alkylene containing one or more hetero atom groups, C₃-C₈ cycloalkylene, substituted C₃-C₈ cycloalkylene, C₂-C₈ unsubstituted or substituted alkenylene (—C═C—), unsustituted or substituted alkynylene (—C₂—), and C₆-C₁₂, unsubstituted or substituted arylene, which may also contain optional hetero atom; and, n=1-5.

7. The composition of claim 1 where the polymer comprises at least one recurring unit with a hydroxyl and/or carboxyl groups.

8. The composition of claim 7, where the polymer further comprises an acid labile group.

9. The composition of claim 7, where the polymer further comprises an absorbing chromophore.

10. The composition of claim 1, where the crosslinker comprises a vinyl ether group.

11. The composition of claim 1, further comprising a crosslinking photoacid generator.

12. The composition of claim 11, where the crosslinking photoacid generator comprises a vinyl ether group.

13. The composition of claim 1, where the amine is selected from tributylamine, triisobutylamine, tripentylamine, triheptylamine, N,N-dicyclohexylmethylamine, trihexylamine, trioctylamine and tri-n-decylamine.

14. A process for forming an image comprising;
a) forming a coating of the bottom photoimageable underlayer coating composition of claim 1 on a substrate;
b) baking the underlayer coating;
c) providing a coating of a photoresist layer over the underlayer coating;
d) imagewise exposing the photoresist and antireflective coating layers to actinic radiation of same wavelength;
e) post-exposure baking the photoresist and antireflective coating layers on the substrate; and,
f) developing the photoresist and antireflective coating layers with an aqueous alkaline solution, thereby forming an pattern in the photoresist and underlayer coating.
